(19) United States
(12) Patent Application Publication
(10) Pub. No.: US 2026/0280597 A1
(43) Pub. Date: Sep. 17, 2026

(54) HARMONIC REJECTION UPCONVERTER ARCHITECTURE WITH IMPROVED HARMONIC REJECTION

(71) Applicant: QUALCOMM Incorporated, San Diego, CA (US)

(72) Inventor: Ojas CHOKSI, San Diego, CA (US)

(21) Appl. No.: 19/080,530

(22) Filed: Mar. 14, 2025

(51) Int. Cl. H04B 1/40; H03F 3/08; H03F 3/45

(52) U.S. Cl. CPC H04B 1/40; H03F 3/087; H03F 3/45475; H03F 2200/451

(57) ABSTRACT

Certain aspects are directed towards a filter circuit. The filter circuit generally includes: a transimpedance amplifier (TIA) configured to generate an in-phase (I) voltage and a complementary I (IB) voltage; a first set of resistive elements coupled to the TIA and configured to perform a weighted combination of the I voltage with an I with a 45° phase offset (I45) voltage and a complementary quadrature with a 45° phase offset (Q45B) voltage to generate an I output signal of the filter circuit; and a second set of resistive elements coupled to the TIA and configured to perform a weighted combination of the IB voltage with a quadrature with a 45 phase offset (Q45) voltage and a complementary I45 (I45B) voltage to generate an IB output signal of the filter circuit.

### TECHNICAL FIELD

Certain aspects of the present disclosure generally relate to electronic circuits and, more particularly, to a harmonic rejection mixer architecture.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more transmit chains.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include a reduction in harmonic components.

Certain aspects are directed towards a filter circuit. The filter circuit generally includes: a first filter including a first transimpedance amplifier (TIA) and a first resistor-capacitor (RC) network coupled to a first output and a second output of the first TIA; a second filter including a second TIA and a second RC network coupled to a first output and a second output of the second TIA; a third filter including a third TIA and a third RC network coupled to a first output and a second output of the third TIA; and a fourth filter including a fourth TIA and a fourth RC network coupled to a first output and a second output of the fourth TIA. In some aspects, the first filter further comprises: a first resistive element and a second resistive element having first terminals coupled to the first output and the second output of the second TIA, respectively, and second terminals coupled to a first output and a second output of the first filter, respectively; and a third resistive element and a fourth resistive element having first terminals coupled to the second output and the first output of the fourth TIA, respectively, and second terminals coupled to the first output and the second output of the first filter, respectively.

Certain aspects are directed towards a method for signal filtering. The method generally includes: generating, via a first filter, an in-phase (I) voltage and a complementary I (IB) voltage; performing, via the first filter, a weighted combination of the I voltage with an I with a 45° phase offset (I45) voltage and a complementary quadrature with a 45° phase offset (Q45B) voltage to generate an I output signal of the first filter; and performing, via the first filter, a weighted combination of the IB voltage with a quadrature with a 45° phase offset (Q45) voltage and a complementary I45 (I45B) voltage to generate an IB output signal of the first filter.

Certain aspects are directed towards a filter circuit. The filter circuit generally includes: a transimpedance amplifier (TIA) configured to generate an in-phase (I) voltage and a complementary I (IB) voltage; a first set of resistive elements coupled to the TIA and configured to perform a weighted combination of the I voltage with an I with a 45° phase offset (I45) voltage and a complementary quadrature with a 45° phase offset (Q45B) voltage to generate an I output signal of the filter circuit; and a second set of resistive elements coupled to the TIA and configured to perform a weighted combination of the IB voltage with a quadrature with a 45 phase offset (Q45) voltage and a complementary I45 (I45B) voltage to generate an IB output signal of the filter circuit.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIGS. 4A and 4B are graphs showing various harmonics of a carrier signal.

FIG. 5 illustrates a transmitter implemented with a harmonic rejection mixer (HRM) architecture, in accordance with certain aspects of the present disclosure.

FIG. 6 illustrates a transmitter implemented with resistive tuning, in accordance with certain aspects of the present disclosure.

FIG. 7 illustrates a transmitter implemented with resistive elements calibrated using eight calibration phases, in accordance with certain aspects of the present disclosure.

FIG. 8 illustrates a transmitter implemented with resistive elements calibrated using four calibration phases, in accordance with certain aspects of the present disclosure.

FIG. 9 illustrates a transmitter implemented with resistive elements calibrated using two calibration phases, in accordance with certain aspects of the present disclosure.

FIG. 10 illustrates an example implementation of a programmable resistive element, in accordance with certain aspects of the present disclosure.

FIG. 11 illustrates an example harmonic rejection mixer architecture, in accordance with certain aspects of the present disclosure.

FIG. 12 is a flow diagram illustrating example operations for signal filtering, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward filter circuitry that may be used to implement a transmitter with a harmonic rejection mixer (HRM) architecture, including resistive tuning to reduce one or more harmonic signals. The filter circuitry may be implemented with resistive elements used to perform a weighted combination of signals of different phases to reduce the one or more harmonic signals. In some aspects, the filter circuitry may include baseband filter (BBF) circuitry that may be part of a transmitter, including digital-to-analog converter (DAC) circuitry and upconverter (UPC) circuitry (e.g., mixers). The DAC circuitry may generate currents of different phases that are provided to the BBF circuitry. The BBF circuitry may generate voltages of different phases that are provided to the UPC circuitry to generate an upconverted signal to be amplified for transmission. In some aspects, the resistive elements may perform the weighted combination of the signals of different phases to reduce one or more harmonic signals that circuit mismatches associated with the DAC circuitry and BBF circuitry may cause. In some cases, one or more calibration phases may be performed to set the resistance of the resistive elements to further take into account the harmonic signal effect from the UPC circuitry, further reducing the one or more harmonic signals.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

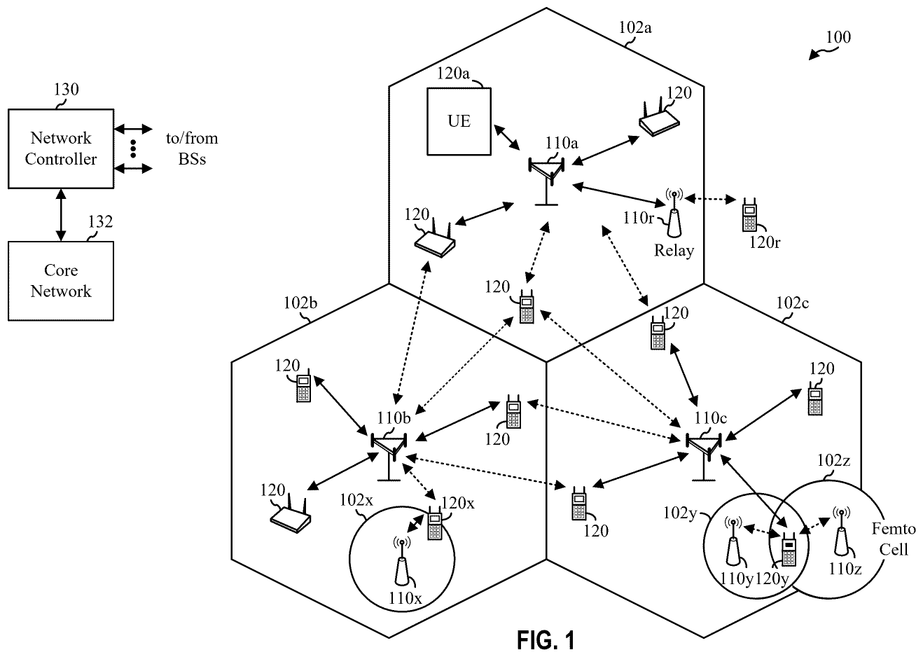

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include filter circuitry implemented with resistive tuning, as described in more detail herein.

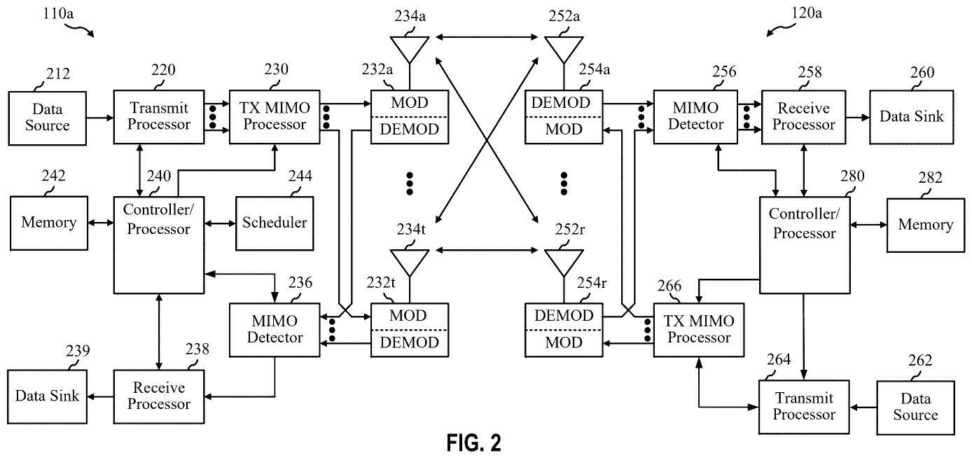

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include filter circuitry implemented with resistive tuning, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

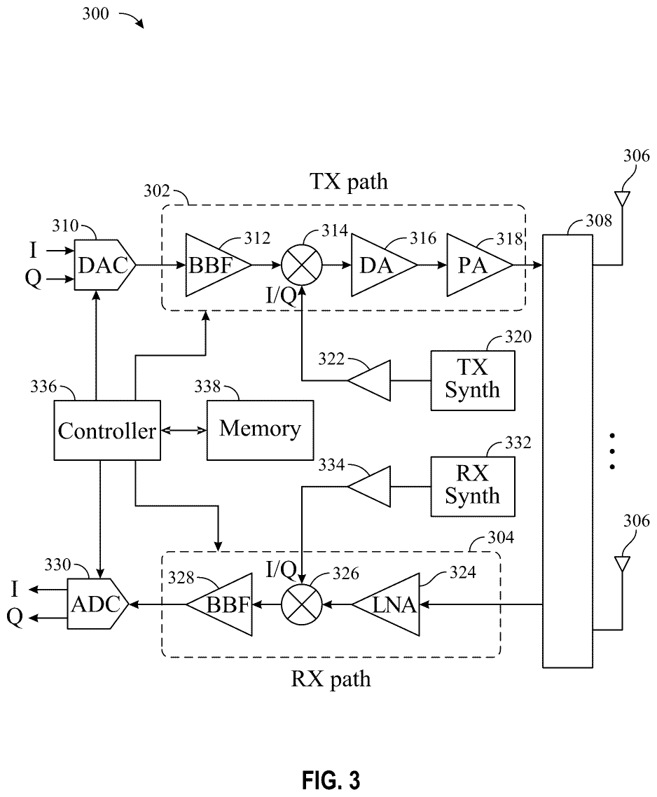

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC. In some aspects, the BBF 312 may be implemented with resistive tuning to reduce one or more harmonic signals, as described in more detail herein.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Harmonic Rejection Upconverter Architecture

Certain aspects of the present disclosure are directed towards a harmonic rejection mixer (HRM)-based transmitter. Specifically, certain aspects provide techniques for calibrating a transmit chain to reduce one or more harmonic signals (e.g., a third-order counter intermodulation product (C_{IM3})) for the HRM-based transmitter in the presence of a local oscillator (LO) path gain/phase errors and mismatches. The techniques described herein may be used in any suitable application, such an HRM-based transmitter operated with any suitable frequency bands.

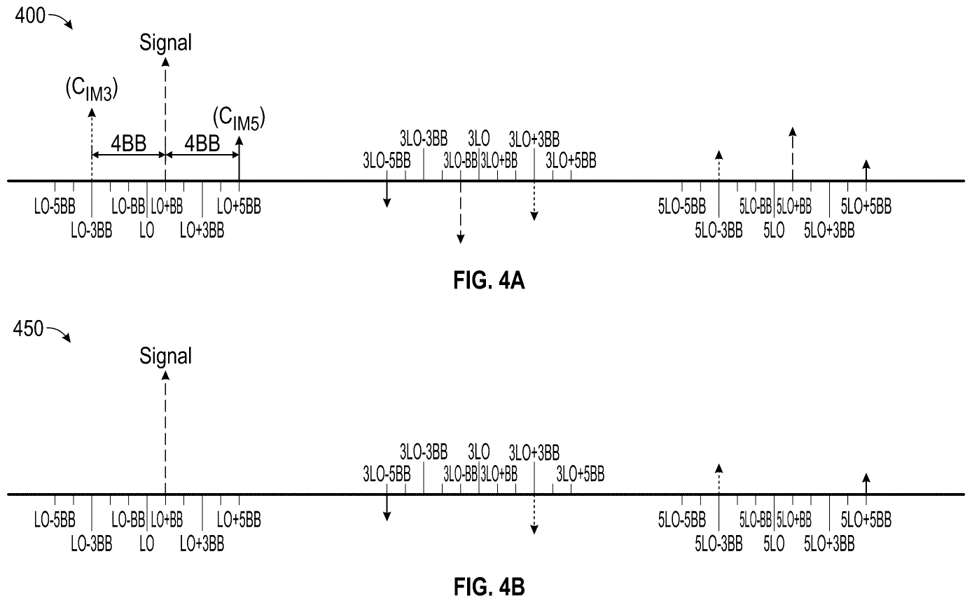

FIG. 4A illustrates a graph 400, 450 showing various harmonics of a carrier signal (e.g., an upconverted synchronization signal block (SSB) signal) of an In-phase/quadrature (IQ) mixer-based transmitter. FIG. 4B illustrates a graph 450 showing various harmonics of a carrier signal of an HRM-based transmitter. For the carrier signal at the LO frequency plus a baseband (BB) frequency (LO+BB), C_{IM3} (e.g., also referred to as a primary 4FMOD (P4FMOD)) is at the LO frequency minus 3 times the BB frequency (LO-3BB) and a fifth-order counter intermodulation product (C_{IM5}) (e.g., also referred to as a secondary 4FMOD (S4FMOD)) is at the LO frequency plus five times the BB frequency (LO+5BB), as shown in graph 400. Modern transmitters (e.g., long-term evolution (LTE)/fifth generation new radio (5GNR)) may have tight specifications in terms of harmonics such as C_{IM3} and C_{IM5} due to stringent emission specifications. C_{IM3} and C_{IM5} may be generated due to non-linearities of BB signaling, which may be caused by the baseband filter (BBF) (e.g., BBF 312 of FIG. 3) and digital-to-analog converter (DAC) (e.g., DAC 310 of FIG. 3).

An in-phase quadrature (IQ) mixer-based transmitter architecture may be used to suppress components at LO-BB, LO+3BB, and LO-5BB (e.g., depending on an I/Q imbalance of the mixer), but may not suppress CIM3 (e.g., P4FMOD) and CIM5 (e.g., S4FMOD) components. Moreover, the components around odd harmonics (e.g., 3LO-BB, 3LO+3BB, 3LO-5BB, 5LO+BB, 5LO-3BB, 5LO+5BB) may not be suppressed. Generally, the components around 3LO and 5LO may be reduced by filtering via an output tank circuit of a driver amplifier (DA) (e.g., DA 316 of FIG. 3). However, the filtering of the 3LO and 5LO components may not be sufficient depending on the quality factor of the tank circuit for a certain loadline. Further, the harmonic component at 3LO-BB may intermodulate with the harmonic at LO+BB due to the non-linearity of the power amplifier (PA) (e.g., PA 318 of FIG. 3) and degrade C_{IM3} (e.g., P4FMOD))

Some HRM-based transmitters may suppress C_{IM3} (e.g., P4FMOD) and C_{IM5} (e.g., S4FMOD) components, as well as 3LO-BB, 5LO+BB signals, as shown in graph 450. However, harmonic components at 3LO+3BB, 3LO-5BB, 5LO-3BB and 5LO+5BB may not be suppressed. The HRM-based transmitter may be implemented with an I path, Q path, I with a 45° offset (I45) path, and Q with a 45° offset (Q45) path to suppress harmonics. However, due to mismatches between the DACs, BBFs, and mixers of the I, Q, I45, and Q45 paths and gain/phase mismatches in the LO chain, the C_{IM3} (e.g., P4FMOD) and C_{IM5} (e.g., S4FMOD) components may not be fully rejected. Moreover, using a DAC and transimpedance amplifier (TIA)-driven passive mixer with an I/Q HRM architecture has advantages in terms of smaller die area, increased linearity, and reduced noise as compared to some other architectures.

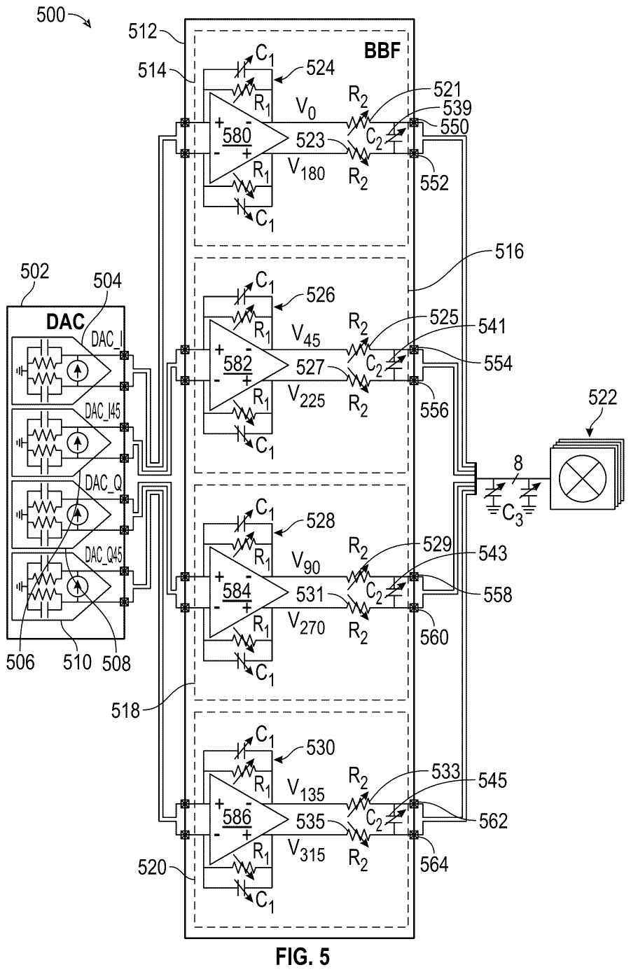

FIG. 5 illustrates a transmitter 500 implemented with an HRM-based architecture, in accordance with certain aspects of the present disclosure. The transmitter 500 may include an I channel generating an I output signal and a complementary I (IB) output signal, a Q channel generating a Q output signal and a complementary Q (QB) output signal, a Q45 channel generating a Q45 output signal and a complementary Q45 (Q45B) output signal, and an I45 channel generating an I45 output signal and a complementary I45 (I45B) output signal.

The transmitter 500 may include a digital-to-analog converter (DAC) circuitry 502. The DAC circuitry 502 may include a set of current-mode DACs 504, 506, 508, 510. The DACs 504, 506, 508, 510 may be implemented as current-steering DACs. Each of the DACs 504, 506, 508, 510 may output a current representing a digital input signal. DAC 504 may generate an in-phase (I) DAC output current at a DAC I output labeled “DAC_I.” DAC 508 may generate a quadrature (Q) DAC output current at a DAC Q output labeled “DAC_Q.” DAC 506 may generate an I with a 45° phase offset (I45) DAC output current at a DAC I45 output labeled “DAC_I45.” DAC 510 may generate a Q with a 45° phase offset (Q45) DAC output current at a DAC Q45 output labeled “DAC_Q45.” The DACs 504, 506, 508, 510 may generate differential output currents, including the DAC_I, DAC_I45, DAC_Q, and DAC_Q45 output currents as well as respective complementary output currents DAC_IB, DAC_I45B, DAC_QB, and DAC_Q45B output currents.

BBF circuitry 512 may be coupled to the outputs of the DAC circuitry 502. The BBF circuitry 512 may include an I BBF 514 that may receive and filter the I DAC output current, an I45 BBF 516 that may receive and filter the I45 DAC output current, a Q BBF 518 that may receive and filter the Q DAC output current, and a Q45 BBF 520 that may receive and filter the Q45 DAC output current. The filtered I, I45, Q, Q45 voltages generated by respective BBFs 514, 516, 518, 520 may be provided to respective mixers 522 forming an upconverter (UPC) load. The upconverted signals from the mixers 522 may be combined and amplified (e.g., using DA 316 and PA 318 of FIG. 3) for transmission.

Thus, the transmitter architecture uses four DAC channels, four BBF channels, and four UPCs (mixers) operating with 0°, 45°, 90° and 135° phases (and complementary phases), respectively. The BBFs 514, 516, 518, 520 may include respective TIAs 524, 526, 528, 530. As shown, the TIAs 524, 526, 528, 530 may be implemented using respective operational amplifiers 580, 582, 584, 586 as well as resistive elements having a resistance R₁ (e.g., hereinafter referred to as “resistive elements R₁”) and capacitive elements having a capacitance C₁ (e.g., hereinafter referred to as “capacitive elements C₁”) that are coupled between respective outputs and respective inputs of the operational amplifier.

Each of the four TIAs converts DAC output currents into output voltages used to drive an associated resistor-capacitor (RC) network that may form a second pole of the filter response. For example, a first output (e.g., at the negative output of amplifier 580) of the TIA 524 may generate a 0° phase voltage V₀ (e.g., also referred to herein as an “I voltage” at an “I voltage node”) and a second output (e.g., at a positive output of the amplifier 580) of the TIA 524 may generate a 180° phase voltage V₁₈₀ (e.g., also referred to herein as an “IB voltage” at an “IB voltage node”). V₀ and V₁₈₀ drive an RC network of BBF 514 formed via resistive elements 521, 523 having a resistance R₂ and a capacitive element 539 having a capacitance C₂. As shown, resistive element 521 may be coupled between the first output of the TIA 524 and an output 550 of BBF 514, resistive element 523 may be coupled between the second output of the TIA 524 and an output 552 of the BBF 514, and a capacitive element 539 coupled between outputs 550, 552.

TIAs 526, 528, 530 are implemented similarly to TIA 524. For example, a first output (e.g., at the negative output of amplifier 582) of the TIA 526 may generate a 45° phase voltage V₄₅ (e.g., also referred to herein as a “I45 voltage” at an “I45 voltage node”) and a second output (e.g., at the positive output of amplifier 582) of the TIA 526 may generate a 225° phase voltage V₂₂₅ (e.g., also referred to herein as a “I45B voltage” at an “I45B voltage node”), where V₄₅ and V₂₂₅ drive an associated RC network including resistive elements 529, 531 having a resistance R₂ and a capacitive element 543 having a capacitance C₂. As shown, resistive element 525 may be coupled between the first output of the TIA 526 and an output 554 of BBF 516, resistive element 527 may be coupled between the second output of the TIA 526 and an output 556 of the BBF 516, and a capacitive element 541 coupled between outputs 554, 556.

A first output (e.g., at the negative output of 584) of the TIA 528 may generate a 90° phase voltage V₉₀ (e.g., also referred to herein as a “Q voltage” at a “Q voltage node”) and a second output (e.g., at the positive output of amplifier 584) of the TIA 528 may generate a 270° phase voltage V₂₇₀ (e.g., also referred to herein as a “QB voltage” at a “QB voltage node”), where V₉₀ and V₂₇₀ drive an associated RC network including resistive elements 529, 531 having a resistance R₂ and a capacitive element 543 having a capacitance C₂ of the BBF 518. Resistive element 529 may be coupled between the first output of the TIA 528 and an output 558 of BBF 518, resistive element 531 may be coupled between the second output of the TIA 528 and an output 560 of the BBF 518, and a capacitive element 543 coupled between outputs 558, 560.

A first output (e.g., at the negative output of amplifier 586) of the TIA 530 may generate a 135° phase voltage V₁₃₅ (e.g., also referred to herein as a “Q45 voltage” at a “Q45 voltage node”) and a second output (e.g., at the positive output of amplifier 586) of the TIA 530 may generate a 315° phase voltage V₃₁₅ (e.g., also referred to herein as a “Q45B voltage” at an “Q45B voltage node”), where V₁₃₅ and V₃₁₅ drive an associated RC network including resistive elements 533, 535 having a resistance R₂ and a capacitive element 545 having a capacitive element C₂ of the BBF 520. Resistive element 533 may be coupled between the first output of the TIA 530 and an output 562 of BBF 520, resistive element 535 may be coupled between the second output of the TIA 530 and an output 564 of the BBF 520, and a capacitive element 545 coupled between outputs 562, 564.

The UPCs (e.g., mixers 522) operate in voltage mode to upconvert the BB voltage signals from the BBF circuitry 512 into radio frequency (RF) at an input of a driver amplifier (DA) (e.g., DA 316 of FIG. 3). The resistive elements R₂ of each of the BBFs 514, 516, 518, 520 and the associated UPC input impedance form an effective impedance divider that is used for gain control in certain bands. A first pole of the BBF (e.g., which may be configured by resistive elements R₁ and capacitive elements C₁ of the TIAs) may be at the edge of the pass band of the BBF. As shown, one or more capacitive elements having a capacitance C₃ (hereinafter referred to as “capacitive elements C₃”) may be coupled to an input of each UPC. The second pole of each BBF may be at a frequency (fₚₒₗₑ₂) in accordance with the equation:

$${f}_{pole 2} = \frac{1}{2 π ( {R}_{2} \vert \vert \frac{{R}_{upc}}{2} ) ( 2 {C}_{2} + {C}_{3} )}$$

where R_{upc} is the input resistance of an associated UPC (mixer). The DAC circuitry 502 introduces a zero to cancel (or at least reduce) the effect of the first pole from the BBF, although DAC aliases still experience second-order filtering by the BBF circuitry.

The four passive UPCs (e.g., mixers 522) are driven by respective differential LO signals where a first differential LO signal has phases 0° and 180°, a second differential LO signal has phases 45° and 225°, a third differential LO signal has phases 90° and 270°, and a fourth differential LO signal has phases 135° and 315°. Due to various mismatches and non-idealities in the LO path, the LO waveforms may not be ideal and suffer from gain and/or phase errors due to duty cycle and delay mismatches, which may reduce the rejection of C_{IM3} and C_{IM5} components. Various mismatches between the four DAC/BBF channels also contribute to reducing the rejection of C_{IM3} and C_{IM5} components. While the phases of the LO signals may be calibrated, some errors may still be generated due to mismatches in delay lines and supply parasitics.

Certain aspects are directed towards an HRM-based transmitter providing increased rejection of C_{IM3} and C_{IM5} components as compared to other transmitter architectures. The transmitter described herein may suppress components at 3LO+3BB, 3LO-5BB, 5LO-3BB, 5LO+5BB, helping to meet emissions (e.g., even in the presence of a low-quality factor (Q) DA). The transmitter allows for reduction of harmonic components (e.g., C_{IM3}) using resistive tuning. Moreover, errors described herein caused by the DAC, BBF, and LO signals may be compensated for (e.g., or at least reduced) with resistance calibration.

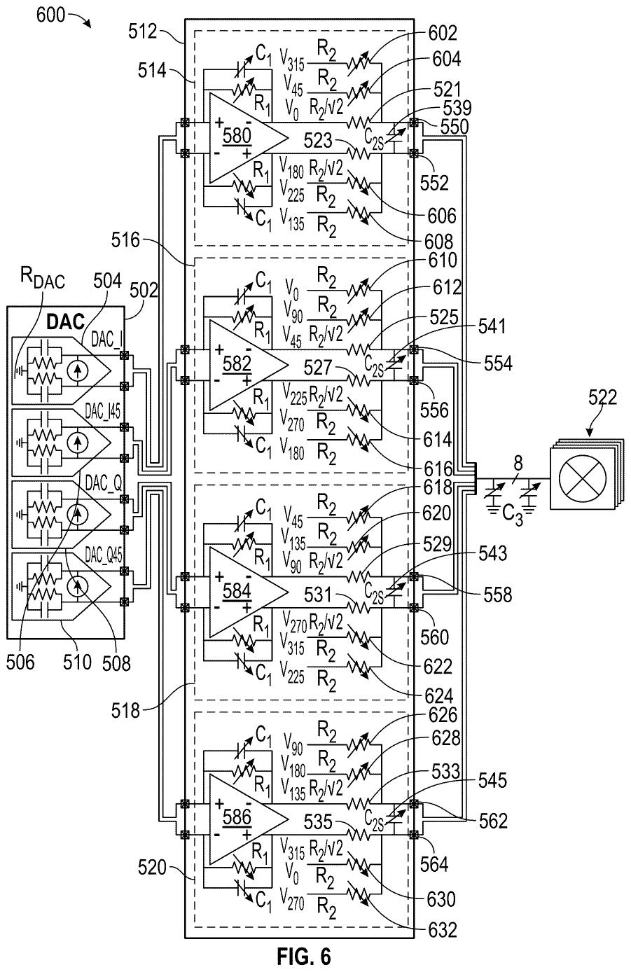

FIG. 6 illustrates a transmitter 600 implemented with resistive tuning, in accordance with certain aspects of the present disclosure. The DAC and BBF outputs from the four channels may be combined with other phases to generate the four differential BBF output signals. For instance, for the I45 channel (e.g., including DAC 506 and BBF 516), combining BBF output signals of the I, I45 and Q channels using weights 1, \sqrt{2}, 1, respectively, cancels (or at least reduces) the third and fifth harmonics caused by the non-linearities of the DAC and BBF. The third and fifth harmonics may be similarly reduced for the other channels. Other harmonics, such as 3LO+3BB, 3LO-5BB, 5LO-3BB, 5LO+5BB components, may be at least partially suppressed in the spectrum.

As shown, the BBF 514 may include a resistive element 602 between output 550 and the V₃₁₅ node, a resistive element 604 between output 550 and the V₄₅ node, a resistive element 606 between output 552 and the V₂₂₅ node, and a resistive element 608 between output 552 and the V₁₃₅ node. The resistive elements 602, 604, 606, 608 may have a resistance R₂ and may be variable. As shown, the resistive elements 521, 523 may have a resistance of R₂/\sqrt{2} and may be variable. Thus, the output voltage at the output 550 may be generated using a weighted combination of V₃₁₅, V₀, V₄₅ using weights 1, \sqrt{2}, 1, respectively. Similarly, the output voltage (e.g., also referred to as an “output signal”) at the output 552 may be generated using a weighted combination of V₁₃₅, V₁₈₀, V₂₂₅ using weights 1, \sqrt{2}, 1, respectively. Thus, the harmonics described herein for the I channel including DAC 504 and BBF 514 may be at least partially suppressed, depending on mismatch.

BBFs 516, 518, 520 may be implemented in a similar manner. For example, the BBF 516 may include a resistive element 610 between output 554 and the V₀ node, a resistive element 612 between output 554 and the V₉₀ node, a resistive element 614 between output 556 and the V₂₇₀ node, and a resistive element 616 between output 556 and the V₁₈₀ node. The resistive elements 610, 612, 614, 616 may have a resistance R₂ and may be variable. As shown, the resistive elements 525, 527 may have a resistance of R₂/V₂ and may be variable. Thus, the output voltage at the output 554 may be generated using a weighted combination of V₀, V₄₅, V₉₀ with weights 1, \sqrt{2}, 1, respectively. Similarly, the output voltage at the output 556 may be generated using a weighted combination of V₁₈₀, V₂₂₅, V₂₇₀ with weights 1, \sqrt{2}, 1, respectively. Thus, harmonics described herein for the I45 channel including DAC 506 and BBF 516 may be at least partially suppressed, depending on mismatch across paths.

BBF 518 may include a resistive element 618 between output 558 and the V₄₅ node, a resistive element 620 between output 554 and the V₁₃₅ node, a resistive element 622 between output 560 and the V₃₁₅ node, and a resistive element 624 between output 560 and the V₂₂₅ node. The resistive elements 618, 620, 622, 624 may have a resistance R₂ and may be variable. As shown, the resistive elements 529, 531 may have a resistance of R₂/V₂ and may be variable. Thus, the output voltage at the output 558 may be generated using a weighted combination of V₄₅, V₉₀, V₁₃₅ with weights 1, \sqrt{2}, 1, respectively. Similarly, the output voltage at the output 560 may be generated using a weighted combination of V₂₂₅, V₂₇₀, V₃₁₅ with weights 1, \sqrt{2}, 1, respectively. Thus, harmonics described herein for the Q channel including DAC 508 and BBF 518 may be at least partially suppressed, depending on mismatch across paths.

BBF 520 may include a resistive element 626 between output 562 and the V₉₀ node, a resistive element 628 between output 562 and the V₁₈₀ node, a resistive element 630 between output 564 and the V₀ node, and a resistive element 632 between output 564 and the V₂₇₀ node. The resistive elements 626, 628, 630, 632 may have a resistance R₂ and may be variable. As shown, the resistive elements 533, 535 may have a resistance of R₂/V₂ and may be variable Thus, the output voltage at the output 562 may be generated using a weighted combination of V₉₀, V₁₃₅, V₁₈₀ with weights 1, \sqrt{2}, 1, respectively. Similarly, the output voltage at the output 564 may be generated using a weighted combination of V₀, V₃₁₅, V₂₇₀ with weights 1, \sqrt{2}, 1, respectively. Thus, harmonics described herein for the Q45 channel including DAC 510 and BBF 520 may be at least partially suppressed, depending on mismatch across paths.

In some aspects, the capacitance C₂ₛ of the capacitive element 539, 541, 543, 545 may be adjusted to control the second pole of the BBF circuitry. In some aspects, the resistive elements of the BBFs may be calibrated to further suppress the harmonics described herein. For example, by calibrating the resistive elements of the BBFs, harmonics caused by the DAC, BBF, as well as the associated mixer may be reduced.

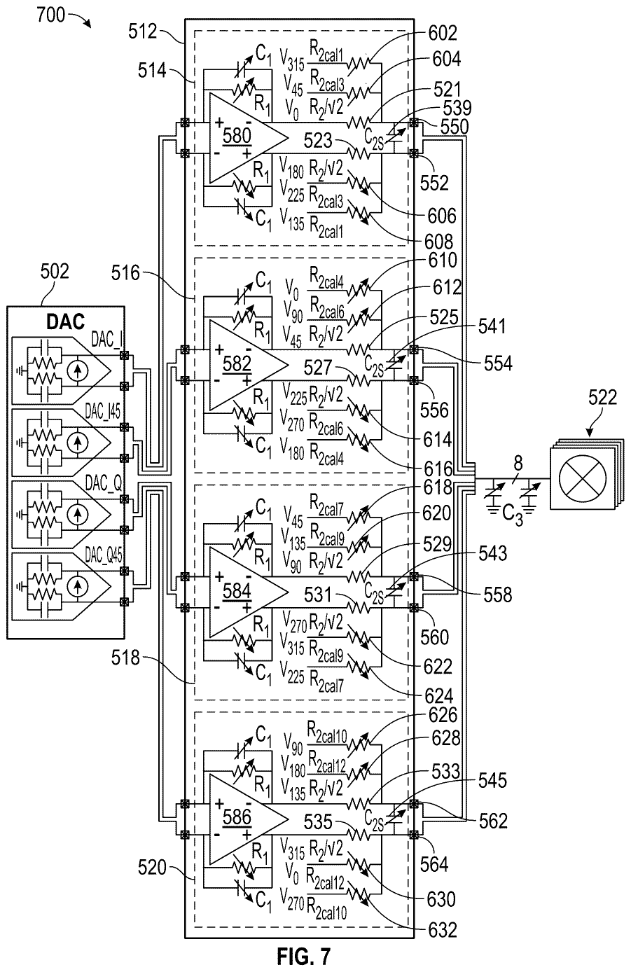

FIG. 7 illustrates a transmitter 700 implemented with resistive elements calibrated using eight calibration phases/steps, in accordance with certain aspects of the present disclosure. Each channel including a DAC, a BBF, and a mixer may be calibrated by enabling one mixer at a time, loading DAC waveform for calibration, and observing the DA output signal for a harmonic (e.g., C_{IM3}). The associated resistive elements for that channel may be then adjusted to reduce the harmonic. In some aspects, two separate calibration phases may be performed for each BBF, yielding eight calibration phases. For instance, during a first calibration phase for BBF 514, the resistances of resistive elements 602, 608 may be swept while monitoring the harmonic at the output of the associated mixer for the I channel. The resistive elements 602, 608 may have the same swept resistance value. That is, the resistance R_{2cal1} for the resistive elements 602, 608 may be determined to minimize (or at least reduce) the harmonic. During a second calibration phase for BBF 514, the resistances of resistive elements 604, 606 may be swept with the associated mixer for the I channel enabled while monitoring the DA output signal for the harmonic. The resistance R_{2cal3} for the resistive elements 604, 606 may be determined to further minimize (or at least reduce) the harmonic.

The same process may be performed for BBFs 516, 518, 520. With BBF 514 being calibrated, first and second calibration phases may be performed for BBF 516, followed by BBF 518, followed by BBF 520. For example, during a first calibration phase for BBF 516, the resistances of resistive elements 610, 616 may be swept with the associated mixer for the I45 channel enabled while monitoring the DA output signal for the harmonic. That is, the resistance R_{2cal4} for the resistive elements 610, 616 may be determined to further minimize (or at least reduce) the harmonic. During a second calibration phase for BBF 516, the resistances of resistive elements 612, 614 may be swept with the associated mixer for the I45 channel enabled while monitoring the DA output signal for the harmonic. The resistance R_{2cal6} for the resistive elements 612, 614 may be determined to further minimize (or at least reduce) the harmonic.

During a first calibration phase for BBF 518, the resistances of resistive elements 618, 624 may be swept with the associated mixer for the Q channel enabled while monitoring the DA output signal for the harmonic. That is, the resistance R_{2cal7} for the resistive elements 618, 624 may be determined to further minimize (or at least reduce) the harmonic. During a second calibration phase for BBF 518, the resistances of resistive elements 620, 622 may be swept with the associated mixer for the Q channel enabled while monitoring the DA output signal for the harmonic. The resistance R_{2cal7} for the resistive elements 620, 622 may be determined to further minimize (or at least reduce) the harmonic.

During a first calibration phase for BBF 520, the resistances of resistive elements 626, 632 may be swept with the associated mixer for the Q45 channel enabled while monitoring the DA output signal for the harmonic. That is, the resistance R_{2cal10} for the resistive elements 626, 632 may be determined to further minimize (or at least reduce) the harmonic. During a second calibration phase for BBF 520, the resistances of resistive elements 628, 630 may be swept with the associated mixer for the Q45 channel enabled while monitoring the DA output signals for the harmonic. The resistance R_{2cal12} for the resistive elements 628, 630 may be determined to further minimize (or at least reduce) the harmonic.

While the calibration techniques described with respect to FIG. 7 include eight calibration phases, fewer calibration phases may be used to reduce the calibration time and power consumption. For example, the transmitter may be calibrated using four calibration phases by calibrating two BBFs together or even two calibration phases by calibrating all four BBFs together. In some aspects, the calibration techniques described may be performed for each of various bands that may be used. The calibrated resistance codes or values may be stored in a lookup table for each of the various bands and used to set the resistances when operating with a specific band. The calibration may be performed per device or together for a series of devices.

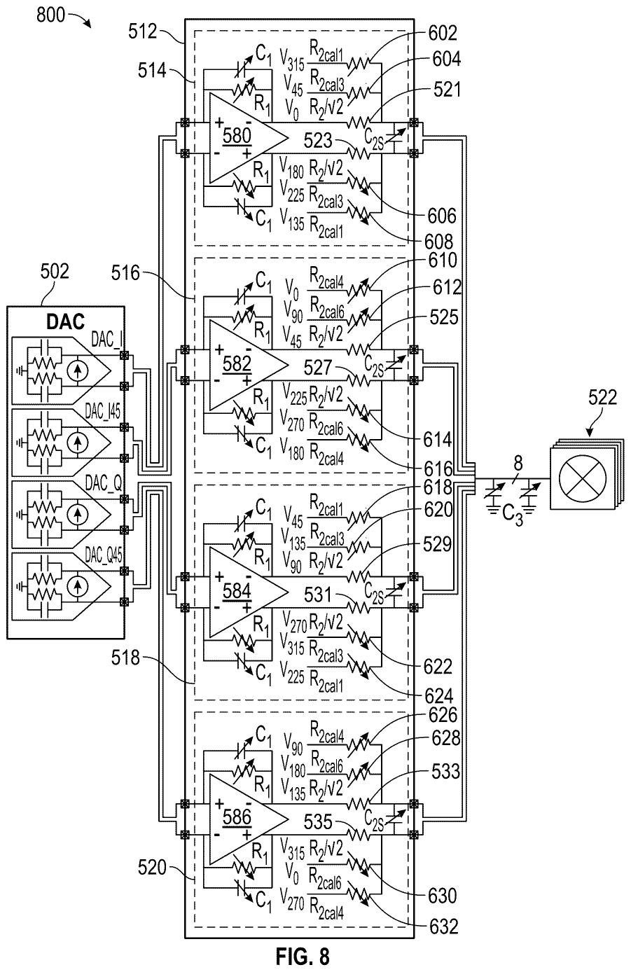

FIG. 8 illustrates a transmitter 800 implemented with resistive elements calibrated using four calibration phases, in accordance with certain aspects of the present disclosure. As described, with four calibration phases, two BBFs may be calibrated together. For instance, during a first calibration phase for BBFs 514, 518, the resistances of resistive elements 602, 608, 618, 624 may be the same and swept with the associated mixers for the I and Q channels being turned on (e.g., enabled). The output signal of the DA may be monitored to determine the resistance R_{2cal1} for resistive elements 602, 608, 618, 624 to minimize (or at least reduce) the harmonic. During a second phase for BBFs 514, 518, the resistances of resistive elements 604, 606, 620, 622 may be the same and swept with the associated mixers for the I and Q channels being turned on. The output signal of the DA may be monitored to determine the resistance R_{2cal3} for resistive elements 604, 606, 620, 622 to further minimize (or at least reduce) the harmonic.

BBFs 516, 520 may be calibrated in a similar manner. For example, during a first calibration phase for BBFs 516, 520, the resistances of resistive elements 610, 616 626, 632 may be swept with associated mixers for the I45 and Q45 channels turned on to identify the resistance R_{2cal4} for resistive elements 610, 616 626, 632. During a second calibration phase for BBFs 516, 520, the resistances of resistive elements 612, 614, 628, 630 may be swept with associated mixers for I45 and Q45 channels turned on to identify the resistance R_{2cal6} for resistive elements 610, 616 626, 632.

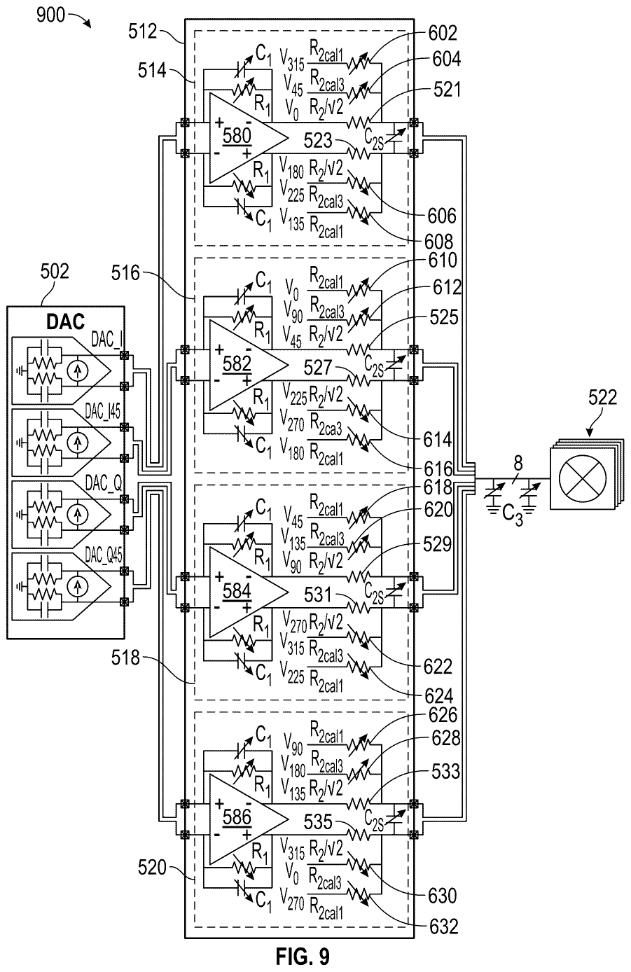

FIG. 9 illustrates a transmitter 900 implemented with resistive elements calibrated using two calibration phases, in accordance with certain aspects of the present disclosure. As described, with two calibration phases, the four BBFs may be calibrated together. For instance, during a first calibration phase for BBFs 514, 516, 518, 520, the resistances of resistive elements 602, 608, 610, 616, 618, 624, 626, 632 may be the same and swept with all mixers 522 turned on. The output signal of the DA may be monitored to determine the resistance R_{2cal1} for resistive elements 602, 608, 610, 616, 618, 624, 626, 632 that minimizes (or at least reduces) the harmonic. During a second phase for BBFs 514, 516, 518, 520, the resistances of resistive elements 604, 606, 612, 614, 620, 622, 628, 630 may be the same and swept with the associated mixers 522 for the I, I45, Q, and Q45 channels being turned on. The output signal of the DA may be monitored to determine the resistance R_{2cal3} for resistive elements 604, 606, 612, 614, 620, 622, 628, 630 that further minimizes (or at least reduces) the harmonic.

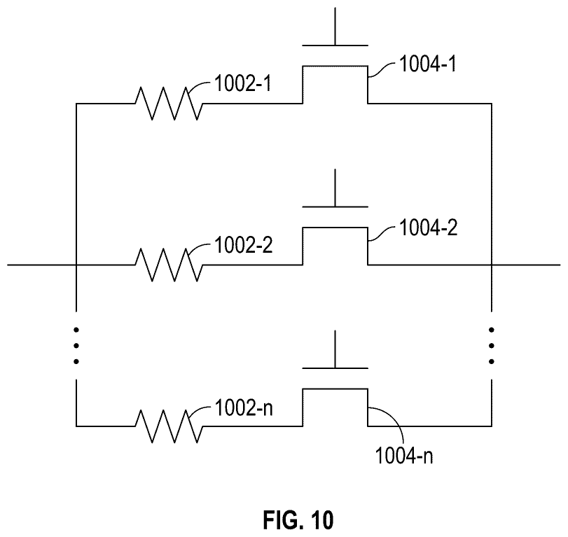

FIG. 10 illustrates an example implementation of a programmable (variable) resistive element, in accordance with certain aspects of the present disclosure. The resistive elements described herein for harmonic suppression may be implemented using a resistor bank with on/off switches (e.g., transistors) or with transistors biased to fine-tune the resistance. For example, as shown, the resistor bank may include a set of resistive elements 1002-1, 1002-2, to 1002-n (n being a positive integer) that may be selectively coupled in parallel using switches implemented as transistors 1004-1, 1004-2, to 1004-n. In this manner, the total resistance of the resistor bank may be adjusted. In some aspects, to provide further fine-tuning of the resistance, the transistors 1004-1, 1004-2, to 1004-n may be biased in a linear region of operation, where the bias voltage (gate voltage) of the transistors may be adjusted to set the on-resistances of the transistors, fine-tuning the overall resistance of the resistor bank.

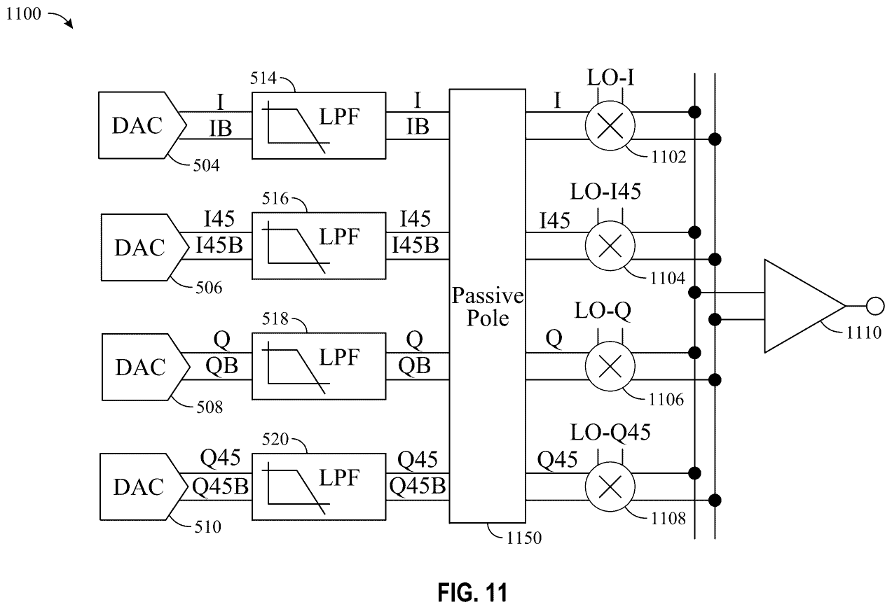

FIG. 11 illustrates an example harmonic rejection mixer architecture 1100, in accordance with certain aspects of the present disclosure. As shown, the BBFs 514, 516, 518, 520 (e.g., low-pass filters (LPFs)) may generate I, I45 Q, and Q45 signals (e.g., and corresponding complementary signals IB, I45B, QB, and Q45B), which may be provided to respective mixers 1102, 1104, 1106, 1108. Mixers 1102, 1104, 1106, 1108 may correspond to the mixers 522 described herein. In some cases, the filtered signals I, I45, Q, and Q45 (e.g., and corresponding complementary signals) from the BBFs 514, 516, 518, 520 may be provided to respective mixers 1102, 1104, 1106, 1108 through a passive pole circuit 1150, such as the capacitive element C₃ described with respect to FIG. 5. As shown, mixer 1102 may receive and upconvert the filtered I and IB signals using I and IB LO signals, mixer 1104 may receive and upconvert the filtered I45 and I45B signals using I45 and I45B LO signals, mixer 1106 may receive and upconvert the filtered Q and QB signals using Q5 and QB LO signals, and the mixer 1108 may receive and upconvert the filtered Q45 and Q45B signals using Q45 and Q45B LO signals. The I, I45, Q, and Q45 outputs of the mixers 1102, 1104, 1106, 1108 may be coupled together and the IB, I45B, QB, and Q45 may be coupled together, generating a differential signal to be amplified using an amplifier 1110 (e.g., a DA such as the DA 316 of FIG. 3 and/or a PA such as the PA 318 of FIG. 3).

Certain aspect of the present disclosure are directed towards a wireless communications circuit with a filter circuit (e.g., BBF circuitry 512) including: a first filter (e.g., BBF 514) including a first TIA (e.g., TIA 524) and a first RC network coupled to a first output (e.g., V₀ node) and a second output (e.g., V₁₈₀ node) of the first TIA; a second filter (e.g., BBF 516) including a second TIA (e.g., TIA 526) and a second RC network coupled to a first output (e.g., V₄₅ node) and a second output (e.g., V₂₂₅ node) of the second TIA; a third filter (e.g., BBF 518) including a third TIA (e.g., TIA 528) and a third RC network coupled to a first output (e.g., V₉₀ node) and a second output (e.g., V₂₇₀ node) of the third TIA; and a fourth filter (e.g., BBF 520) including a fourth TIA (e.g., TIA 530) and a fourth RC network coupled to a first output (e.g., V₁₃₅ node) and a second output (e.g., V₃₁₅ node) of the fourth TIA.

The first filter may include: a first resistive element (e.g., resistive element 604) and a second resistive element (e.g., resistive element 606) having first terminals coupled to the first output (e.g., V₄₅ node) and the second output (e.g., V₂₂₅ node) of the second TIA, respectively, and second terminals coupled to a first output (e.g., output 550) and a second output (e.g., output 552) of the first filter, respectively; and a third resistive element (e.g., resistive element 602) and a fourth resistive element (e.g., resistive element 608) having first terminals coupled to the second output (e.g., V₃₁₅ node) and the first output (e.g., V₁₃₅ node) of the fourth TIA, respectively, and second terminals coupled to the first output (e.g., output 550) and the second output (e.g., output 552) of the first filter, respectively.

In some aspects, the second filter further comprises: a fifth resistive element (e.g., resistive element 612) and a sixth resistive element (e.g., resistive element 614) having first terminals coupled to the first output (e.g., V₉₀ node) and the second output (e.g., V₂₇₀) of the third TIA, respectively, and second terminals coupled to a first output (e.g., output 554) and a second output (e.g., output 556) of the second filter, respectively; and a seventh resistive element (e.g., resistive element 610) and an eighth resistive element (e.g., resistive element 616) having first terminals coupled to the first output (e.g., V₀ node) and the second output (e.g., V₁₈₀ node) of the first TIA, respectively, and second terminals coupled to the first output (e.g., output 554) and the second output (e.g., output 556) of the second filter, respectively.

In some aspects, the third filter further comprises: a ninth resistive element (e.g., resistive element 620) and a tenth resistive element (e.g., resistive element 622) having first terminals coupled to the first output (e.g., V₁₃₅ node) and the second output (e.g., V₃₁₅ node) of the fourth TIA, respectively, and second terminals coupled to a first output (e.g., output 558) and a second output (e.g., output 560) of the third filter, respectively; and an eleventh resistive element (e.g., resistive element 618) and a twelfth resistive element (e.g., resistive element 624) having first terminals coupled to the first output (e.g., V₄₅ node) and the second output (e.g., V₂₂₅ node) of the second TIA, respectively, and second terminals coupled to the first output (e.g., output 558) and the second output (e.g., output 560) of the third filter, respectively.

In some aspects, the fourth filter further comprises: a thirteenth resistive element (e.g., resistive element 628) and a fourteenth resistive element (e.g., resistive element 630) having first terminals coupled to the second output (e.g., V₁₈₀ node) and the first output (e.g., V₀ node) of the first TIA, respectively, and second terminals coupled to a first output (e.g., output 562) and a second output (e.g., output 564) of the fourth filter, respectively; and a fifteenth resistive element (e.g., resistive element 626) and a sixteenth resistive element (e.g., resistive element 632) having first terminals coupled to the first output (e.g., output V₉₀ node) and the second output (e.g., V₂₇₀ node) of the third TIA, respectively, and second terminals coupled to the first output (e.g., output 562) and the second output (e.g., output 564) of the fourth filter, respectively.

In some aspects, the first output and the second output of the first TIA comprise an in-phase (I) voltage node and a complementary I (IB) voltage node, respectively. The first output and the second output of the second TIA may include an I with a 45° phase offset (I45) voltage node and a complementary I45 (I45B) voltage node, respectively. The first output and the second output of the third TIA may include a quadrature (Q) voltage node and a complementary Q (QB) voltage node, respectively. The first output and the second output of the fourth TIA may include a Q with a 45° phase offset (Q45) voltage node and a complementary Q45 (Q45B) voltage node, respectively.

In some aspects, the first RC network may include: a set of resistive elements (e.g., resistive elements 521, 523) having first terminals coupled to the first output (e.g., V₀ node) and the second output (e.g., V₁₈₀ node) of the first TIA and second terminals coupled to the first output (e.g., output 550) and the second output (e.g., output 552) of the first filter; and a capacitive element (e.g., capacitive element 539) coupled between the first output and the second output of the first filter.

In some aspects, each of the first resistive element, the second resistive element, the third resistive element, and the fourth resistive element has a resistance R. Each of a set of resistive elements of the RC network may have a resistance of R/\sqrt{2}.

In some aspects, the wireless communications circuit may also include: a first mixer (e.g., mixer 1102 of FIG. 11) having a first input and a second input coupled to the first output and the second output of the first filter, respectively; a second mixer (e.g., mixer 1104) having a first input and a second input coupled to the first output and the second output of the second filter, respectively; a third mixer (e.g., mixer 1106) having a first input and a second input coupled to the first output and the second output of the third filter, respectively; and a fourth mixer (e.g., mixer 1108) having a first input and a second input coupled to the first output and the second output of the fourth filter, respectively.

In some aspects the wireless communications circuit includes: a first DAC (e.g., DAC 504) having a first output and a second output coupled to a first input and a second input of the first filter, respectively; a second DAC (e.g., DAC 506) having a first output and a second output coupled to a first input and a second input of the second filter, respectively; a third DAC (e.g., DAC 508) having a first output and a second output coupled to a first input and a second input of the third filter, respectively; and a fourth DAC (e.g., DAC 510) having a first output and a second output coupled to a first input and a second input of the fourth filter, respectively. The first DAC, the second DAC, the third DAC, and the fourth DAC may be current-mode DACs.

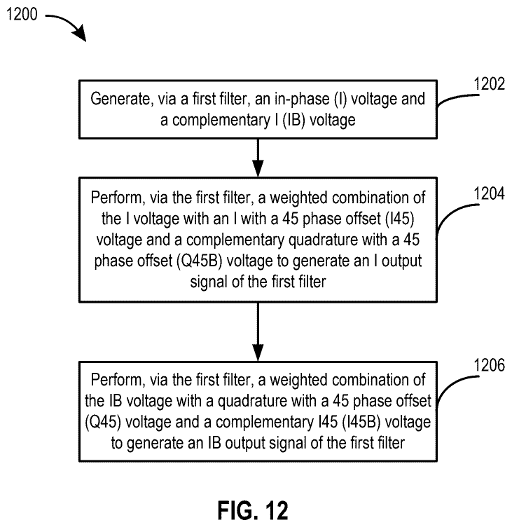

FIG. 12 is a flow diagram illustrating example operations 1200 for signal filtering, in accordance with certain aspects of the present disclosure. The operations 1200 may be performed, for example, by a filter circuit such as the BBF circuitry 512 of FIGS. 6-9 and/or a transmitter such as the transmitters 600, 700, 800, or 900 of FIGS. 6-9.

At block 1202, the filter circuitry may generate, via a first filter (e.g., BBF 514), an I voltage (e.g., V₀) and an IB voltage (e.g., V₁₈₀). At block 1204, the filter circuitry may perform, via the first filter, a weighted combination of the I voltage with an I45 voltage (e.g., V₄₅) and a Q45B voltage (e.g., V₃₁₅) to generate an I output signal of the first filter. At block 1206, the filter circuitry performs, via the first filter, a weighted combination of the IB voltage with a Q45 voltage (e.g., V₁₃₅) and an I45B voltage (e.g., V₂₂₅) to generate an IB output signal of the first filter.

In some aspects, the filter circuitry may also generate, via a second filter (e.g., filter BBF 516), the I45 voltage and the I45B voltage. The filter circuitry may perform, via the second filter, a weighted combination of the I45 voltage with the I voltage and a Q voltage (e.g., V₉₀) to generate an I45 output signal of the second filter. The filter circuitry may also perform, via the second filter, a weighted combination of the I45B voltage with the IB voltage and a QB voltage (e.g., V₂₇₀) to generate an I45B output signal of the second filter.

In some aspects, the filter circuitry may generate, via a third filter (e.g., BBF 518), the Q voltage and the QB voltage. The filter circuitry may perform, via the third filter, a weighted combination of the Q voltage with the I45 voltage (e.g., V₄₅) and the Q45 voltage (e.g., V₁₃₅) to generate a Q output signal of the third filter, and may perform, via the third filter, a weighted combination of the QB voltage with the I45B voltage (e.g., V₂₂₅) and the Q45B voltage (e.g., V₃₁₅) to generate a QB output signal of the third filter.

In some aspects, the filter circuitry may generate, via a fourth filter (e.g., BBF 520), the Q45 voltage and the Q45B voltage. The filter circuitry may perform, via the fourth filter, a weighted combination of the Q45 voltage with the Q voltage (e.g., V₉₀) and the IB voltage (e.g., V₁₈₀) to generate a Q45 output signal of the fourth filter, and perform, via the fourth filter, a weighted combination of the Q45B voltage with the QB voltage (e.g., V₂₇₀) and the I voltage (e.g., V₀) to generate a Q45B output signal of the fourth filter.

In some aspects, the filter circuitry may provide the I output signal and the IB output signal to the I output and the IB output of the first filter through a resistor-capacitor (RC) network (e.g., including resistive elements 521, 523 and capacitive element 539). Performing the weighted combination of the I voltage with the I45 voltage and the Q45B voltage may include combining the I45 voltage, the I voltage, and the Q45B voltage using weights 1, \sqrt{2}, and 1, respectively.

In some aspects, to generate the I voltage and the IB voltage, the filter circuitry may convert, via a TIA (e.g., TIA 524), a DAC I current to the I voltage and convert, via the TIA, a DAC IB current to the IB voltage. In some aspects, the transmitter may generate, via a DAC (e.g., DAC 504), the DAC I current and the DAC IB current based on a digital input signal. In some aspects, the transmitter may generate, via a mixer (e.g., one of mixers 522), an upconverted signal based on the I voltage and the IB voltage.

The resistor combinations (e.g., to perform a weighted combination of signals) as described herein reduce third and fifth harmonics caused by DAC and BBF nonlinearities, and hence, improves C_{IM3} (e.g., P4FMOD) and C_{IM5} (e.g., S4FMOD). The resistor combinations suppress unwanted components such as components at 3LO+3BB, 3LO-5BB, 5LO-3BB, 5LO+5BB frequencies, helping to reduce emissions even with low DA tank Q. The architecture described herein provides a means to calibrate C_{IM3} (e.g., P4FMOD) by resistor tuning, which may not otherwise be possible with a traditional HRM-based mixer architecture. Errors due to mismatch between the DAC and BBF channels as well as gain/phase mismatch of LO waveforms may be compensated for with resistor calibration (e.g., using eight, four, or two calibration phases), avoiding other complex/power hungry 4FMOD calibrations.

### EXAMPLE ASPECTS

In addition to the various aspects described above, specific combinations of aspects are within the scope of the present disclosure, some of which are detailed below:

Aspect 1: A wireless communications circuit comprising: a filter circuit including: a first filter including a first transimpedance amplifier (TIA) and a first resistor-capacitor (RC) network coupled to a first output and a second output of the first TIA; a second filter including a second TIA and a second RC network coupled to a first output and a second output of the second TIA; a third filter including a third TIA and a third RC network coupled to a first output and a second output of the third TIA; and a fourth filter including a fourth TIA and a fourth RC network coupled to a first output and a second output of the fourth TIA, wherein the first filter further comprises: a first resistive element and a second resistive element having first terminals coupled to the first output and the second output of the second TIA, respectively, and second terminals coupled to a first output and a second output of the first filter, respectively; and a third resistive element and a fourth resistive element having first terminals coupled to the second output and the first output of the fourth TIA, respectively, and second terminals coupled to the first output and the second output of the first filter, respectively.

Aspect 2: The filter circuit of Aspect 1, wherein the second filter further comprises: a fifth resistive element and a sixth resistive element having first terminals coupled to the first output and the second output of the third TIA, respectively, and second terminals coupled to a first output and a second output of the second filter, respectively; and a seventh resistive element and an eighth resistive element having first terminals coupled to the first output and the second output of the first TIA, respectively, and second terminals coupled to the first output and the second output of the second filter, respectively.

Aspect 3: The filter circuit of Aspect 2, wherein the third filter further comprises: a ninth resistive element and a tenth resistive element having first terminals coupled to the first output and the second output of the fourth TIA, respectively, and second terminals coupled to a first output and a second output of the third filter, respectively; and an eleventh resistive element and a twelfth resistive element having first terminals coupled to the first output and the second output of the second TIA, respectively, and second terminals coupled to the first output and the second output of the third filter, respectively.

Aspect 4: The filter circuit of Aspect 3, wherein the fourth filter further comprises: a thirteenth resistive element and a fourteenth resistive element having first terminals coupled to the second output and the first output of the first TIA, respectively, and second terminals coupled to a first output and a second output of the fourth filter, respectively; and a fifteenth resistive element and a sixteenth resistive element having first terminals coupled to the first output and the second output of the third TIA, respectively, and second terminals coupled to the first output and the second output of the fourth filter, respectively.

Aspect 5: The filter circuit according to any of Aspects 1-4, wherein: the first output and the second output of the first TIA comprise an in-phase (I) voltage node and a complementary I (IB) voltage node, respectively; the first output and the second output of the second TIA comprise an I with a 45° phase offset (I45) voltage node and a complementary I45 (I45B) voltage node, respectively; the first output and the second output of the third TIA comprise a quadrature (Q) voltage node and a complementary Q (QB) voltage node, respectively; and the first output and the second output of the fourth TIA comprise a Q with a 45° phase offset (Q45) voltage node and a complementary Q45 (Q45B) voltage node, respectively.

Aspect 6: The filter circuit according to any of Aspects 1-5, wherein the first RC network comprises: a set of resistive elements having first terminals coupled to the first output and the second output of the first TIA and second terminals coupled to the first output and the second output of the first filter; and a capacitive element coupled between the first output and the second output of the first filter.

Aspect 7: The filter circuit according to any of Aspects 1-6, wherein: each of the first resistive element, the second resistive element, the third resistive element, and the fourth resistive element has a resistance R; and each of a set of resistive elements of the RC network have a resistance of R/\sqrt{2}.

Aspect 8: The wireless communications circuit according to any of Aspects 1-7, further comprising: a first mixer having a first input and a second input coupled to the first output and the second output of the first filter, respectively; a second mixer having a first input and a second input coupled to the first output and the second output of the second filter, respectively; a third mixer having a first input and a second input coupled to the first output and the second output of the third filter, respectively; and a fourth mixer having a first input and a second input coupled to the first output and the second output of the fourth filter, respectively.

Aspect 9: The wireless communications circuit according to any of Aspects 1-8, further comprising: a first digital-to-analog converter (DAC) having a first output and a second output coupled to a first input and a second input of the first filter, respectively; a second DAC having a first output and a second output coupled to a first input and a second input of the second filter, respectively; a third DAC having a first output and a second output coupled to a first input and a second input of the third filter, respectively; and a fourth DAC having a first output and a second output coupled to a first input and a second input of the fourth filter, respectively.

Aspect 10: The wireless communications circuit of Aspect 9, wherein the first DAC, the second DAC, the third DAC, and the fourth DAC comprise current-mode DACs.

Aspect 11: A method for signal filtering, comprising: generating, via a first filter, an in-phase (I) voltage and a complementary I (IB) voltage; performing, via the first filter, a weighted combination of the I voltage with an I with a 45° phase offset (I45) voltage and a complementary quadrature with a 45° phase offset (Q45B) voltage to generate an I output signal of the first filter; and performing, via the first filter, a weighted combination of the IB voltage with a quadrature with a 45° phase offset (Q45) voltage and a complementary I45 (I45B) voltage to generate an IB output signal of the first filter.

Aspect 12: The method of Aspect 11, comprising: generating, via a second filter, the I45 voltage and the I45B voltage; performing, via the second filter, a weighted combination of the I45 voltage with the I voltage and a quadrature (Q) voltage to generate an I45 output signal of the second filter; and performing, via the second filter, a weighted combination of the I45B voltage with the IB voltage and a complementary quadrature (QB) voltage to generate an I45B output signal of the second filter.

Aspect 13: The method of Aspect 11 or 12, comprising: generating, via a third filter, a Q voltage and a QB voltage; performing, via the third filter, a weighted combination of the Q voltage with the I45 voltage and the Q45 voltage to generate a Q output signal of the third filter; and performing, via the third filter, a weighted combination of the QB voltage with the I45B voltage and the Q45B voltage to generate a QB output signal of the third filter.

Aspect 14: The method according to any of Aspects 11-13, comprising: generating, via a fourth filter, the Q45 voltage and the Q45B voltage; performing, via the fourth filter, a weighted combination of the Q45 voltage with a Q voltage and the IB voltage to generate a Q45 output signal of the fourth filter; and performing, via the fourth filter, a weighted combination of the Q45B voltage with a QB voltage and the I voltage to generate a Q45B output signal of the fourth filter.

Aspect 15: The method according to any of Aspects 11-14, further comprising providing the I output signal and the IB output signal to an I output and an IB output of the first filter through a resistor-capacitor (RC) network.

Aspect 16: The method of Aspect 15, wherein performing the weighted combination of the I voltage with the I45 voltage and the Q45B voltage comprises combining the I45 voltage, the I voltage, and the Q45 voltage using weights 1, 1/\sqrt{2}, and 1, respectively.

Aspect 17: The method according to any of Aspects 11-16, wherein generating the I voltage and the IB voltage comprises: converting, via a transimpedance amplifier (TIA), an I current to the I voltage; and converting, via the TIA, an IB current to the IB voltage.

Aspect 18: The method of Aspect 17, further comprising generating, via a digital-to-analog converter (DAC), the I current and the IB current based on a digital input signal.

Aspect 19: The method according to any of Aspects 11-18, further comprising generating, via a mixer, an upconverted signal based on the I voltage and the IB voltage.

Aspect 20: A filter circuit comprising: a transimpedance amplifier (TIA) configured to generate an in-phase (I) voltage and a complementary I (IB) voltage; a first set of resistive elements coupled to the TIA and configured to perform a weighted combination of the I voltage with an I with a 45° phase offset (I45) voltage and a complementary quadrature with a 45° phase offset (Q45B) voltage to generate an I output signal of the filter circuit; and a second set of resistive elements coupled to the TIA and configured to perform a weighted combination of the IB voltage with a quadrature with a 45 phase offset (Q45) voltage and a complementary I45 (I45B) voltage to generate an IB output signal of the filter circuit.

### ADDITIONAL CONSIDERATIONS

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A wireless communications circuit comprising:
a filter circuit including:
a first filter including a first transimpedance amplifier (TIA) and a first resistor-capacitor (RC) network coupled to a first output and a second output of the first TIA;
a second filter including a second TIA and a second RC network coupled to a first output and a second output of the second TIA;
a third filter including a third TIA and a third RC network coupled to a first output and a second output of the third TIA; and
a fourth filter including a fourth TIA and a fourth RC network coupled to a first output and a second output of the fourth TIA, wherein the first filter further comprises:
a first resistive element and a second resistive element having first terminals coupled to the first output and the second output of the second TIA, respectively, and second terminals coupled to a first output and a second output of the first filter, respectively; and
a third resistive element and a fourth resistive element having first terminals coupled to the second output and the first output of the fourth TIA, respectively, and second terminals coupled to the first output and the second output of the first filter, respectively.

2. The filter circuit of claim 1, wherein the second filter further comprises:
a fifth resistive element and a sixth resistive element having first terminals coupled to the first output and the second output of the third TIA, respectively, and second terminals coupled to a first output and a second output of the second filter, respectively; and
a seventh resistive element and an eighth resistive element having first terminals coupled to the first output and the second output of the first TIA, respectively, and second terminals coupled to the first output and the second output of the second filter, respectively.

3. The filter circuit of claim 2, wherein the third filter further comprises:
a ninth resistive element and a tenth resistive element having first terminals coupled to the first output and the second output of the fourth TIA, respectively, and second terminals coupled to a first output and a second output of the third filter, respectively; and
an eleventh resistive element and a twelfth resistive element having first terminals coupled to the first output and the second output of the second TIA, respectively, and second terminals coupled to the first output and the second output of the third filter, respectively.

4. The filter circuit of claim 3, wherein the fourth filter further comprises:
a thirteenth resistive element and a fourteenth resistive element having first terminals coupled to the second output and the first output of the first TIA, respectively, and second terminals coupled to a first output and a second output of the fourth filter, respectively; and
a fifteenth resistive element and a sixteenth resistive element having first terminals coupled to the first output and the second output of the third TIA, respectively, and second terminals coupled to the first output and the second output of the fourth filter, respectively.

5. The filter circuit of claim 1, wherein:
the first output and the second output of the first TIA comprise an in-phase (I) voltage node and a complementary I (IB) voltage node, respectively;
the first output and the second output of the second TIA comprise an I with a 45° phase offset (I45) voltage node and a complementary I45 (I45B) voltage node, respectively;
the first output and the second output of the third TIA comprise a quadrature (Q) voltage node and a complementary Q (QB) voltage node, respectively; and
the first output and the second output of the fourth TIA comprise a Q with a 45° phase offset (Q45) voltage node and a complementary Q45 (Q45B) voltage node, respectively.

6. The filter circuit of claim 1, wherein the first RC network comprises:
a set of resistive elements having first terminals coupled to the first output and the second output of the first TIA and second terminals coupled to the first output and the second output of the first filter; and
a capacitive element coupled between the first output and the second output of the first filter.

7. The filter circuit of claim 1, wherein:
each of the first resistive element, the second resistive element, the third resistive element, and the fourth resistive element has a resistance R; and
each of a set of resistive elements of the RC network have a resistance of R/\sqrt{2}.

8. The wireless communications circuit of claim 1, further comprising:
a first mixer having a first input and a second input coupled to the first output and the second output of the first filter, respectively;
a second mixer having a first input and a second input coupled to the first output and the second output of the second filter, respectively;
a third mixer having a first input and a second input coupled to the first output and the second output of the third filter, respectively; and
a fourth mixer having a first input and a second input coupled to the first output and the second output of the fourth filter, respectively.

9. The wireless communications circuit of claim 1, further comprising:
a first digital-to-analog converter (DAC) having a first output and a second output coupled to a first input and a second input of the first filter, respectively;
a second DAC having a first output and a second output coupled to a first input and a second input of the second filter, respectively;
a third DAC having a first output and a second output coupled to a first input and a second input of the third filter, respectively; and
a fourth DAC having a first output and a second output coupled to a first input and a second input of the fourth filter, respectively.

10. The wireless communications circuit of claim 9, wherein the first DAC, the second DAC, the third DAC, and the fourth DAC comprise current-mode DACs.

11. A method for signal filtering, comprising:
generating, via a first filter, an in-phase (I) voltage and a complementary I (IB) voltage;
performing, via the first filter, a weighted combination of the I voltage with an I with a 45° phase offset (I45) voltage and a complementary quadrature with a 45° phase offset (Q45B) voltage to generate an I output signal of the first filter; and
performing, via the first filter, a weighted combination of the IB voltage with a quadrature with a 45° phase offset (Q45) voltage and a complementary I45 (I45B) voltage to generate an IB output signal of the first filter.

12. The method of claim 11, comprising:
generating, via a second filter, the I45 voltage and the I45B voltage;
performing, via the second filter, a weighted combination of the I45 voltage with the I voltage and a quadrature (Q) voltage to generate an I45 output signal of the second filter; and
performing, via the second filter, a weighted combination of the I45B voltage with the IB voltage and a complementary quadrature (QB) voltage to generate an I45B output signal of the second filter.

13. The method of claim 11, comprising:
generating, via a third filter, a Q voltage and a QB voltage;
performing, via the third filter, a weighted combination of the Q voltage with the I45 voltage and the Q45 voltage to generate a Q output signal of the third filter; and
performing, via the third filter, a weighted combination of the QB voltage with the I45B voltage and the Q45B voltage to generate a QB output signal of the third filter.

14. The method of claim 11, comprising:
generating, via a fourth filter, the Q45 voltage and the Q45B voltage;
performing, via the fourth filter, a weighted combination of the Q45 voltage with a Q voltage and the IB voltage to generate a Q45 output signal of the fourth filter; and
performing, via the fourth filter, a weighted combination of the Q45B voltage with a QB voltage and the I voltage to generate a Q45B output signal of the fourth filter.

15. The method of claim 11, further comprising providing the I output signal and the IB output signal to an I output and an IB output of the first filter through a resistor-capacitor (RC) network.

16. The method of claim 15, wherein performing the weighted combination of the I voltage with the I45 voltage and the Q45B voltage comprises combining the I45 voltage, the I voltage, and the Q45 voltage using weights 1, 1/\sqrt{2}, and 1, respectively.

17. The method of claim 11, wherein generating the I voltage and the IB voltage comprises:
converting, via a transimpedance amplifier (TIA), an I current to the I voltage; and
converting, via the TIA, an IB current to the IB voltage.

18. The method of claim 17, further comprising generating, via a digital-to-analog converter (DAC), the I current and the IB current based on a digital input signal.

19. The method of claim 11, further comprising generating, via a mixer, an upconverted signal based on the I voltage and the IB voltage.

20. A filter circuit comprising:
a transimpedance amplifier (TIA) configured to generate an in-phase (I) voltage and a complementary I (IB) voltage;
a first set of resistive elements coupled to the TIA and configured to perform a weighted combination of the I voltage with an I with a 45° phase offset (I45) voltage and a complementary quadrature with a 45° phase offset (Q45B) voltage to generate an I output signal of the filter circuit; and
a second set of resistive elements coupled to the TIA and configured to perform a weighted combination of the IB voltage with a quadrature with a 45 phase offset (Q45) voltage and a complementary I45 (I45B) voltage to generate an IB output signal of the filter circuit.
